(19) United States
(12) Patent Application Publication
(10) Pub. No.: US 2019/0135616 A1
(43) Pub. Date: May 9, 2019

(54) DEEP LEARNING SOFTWARE ENHANCED MICROELECTROMECHANICAL SYSTEMS (MEMS) BASED INERTIAL MEASUREMENT UNIT (IMU)

(71) Applicant: University of Dayton, Dayton, OH (US)

(72) Inventors: Priyanka Aggarwal, Virginia Beach, VA (US); Vamsy Chodavarapu, Beavercreek, OH (US)

(21) Appl. No.: 16/178,133

(22) Filed: Nov. 1, 2018

Related U.S. Application Data
(60) Provisional application No. 62/581,304, filed on Nov. 3, 2017.

(51) Int. Cl. B81B 7/02; G06N 3/04; G06N 3/08; G06N 7/00

(52) U.S. Cl. CPC B81B 7/02; G06N 3/0472; B81B 2207/012; G06N 7/005; B81B 2201/0242; G06N 3/08

(57) ABSTRACT

Methods for improving the performance of low-cost tactical grade MEMS IMUs to reach high-end tactical grade or inertial navigation grade performance levels include exploiting advanced Deep Learning and effective stochastic models for sensor errors. The methods offer a SWaP-C alternative in a low-cost, compact weight platform compared to expensive and bulky higher grade Fiber Optic Gyroscopes and Ring Laser Gyroscopes.

### CROSS-REFERENCES TO RELATED APPLICATIONS

This application claims the benefit of priority to U.S. Provisional Application Ser. No. 62/581,304, filed Nov. 3, 2017, the entire contents of which are incorporated herein by reference.

### FIELD

Embodiments of the present disclosure relate to the development of autonomous, independent and self-correcting microelectromechanical system (MEMS) based sensors for self-driving, mobile, and wearable applications, which have robust self-calibrating and error mitigating/modeling requirements and should be robust enough to operate under diverse environmental conditions at an affordable cost.

### BACKGROUND

To reduce the overall system cost, weight, size and power requirements, MEMS inertial sensors are highly coveted for various applications ranging from guidance systems and rescue operations to consumer applications, including, but not limited to applications that monitor human physical activity, pedestrian navigation systems, or smart watches. However, these inertial sensors use smaller proof mass, which reduces their accuracy when compared to high-end sensors with larger proof mass. Also, in an attempt to reduce cost, manufacturers produce these inertial sensors in large volumes, thereby making individual calibration difficult. This miniaturization and cost reduction influences the performance characteristics of sensors. MEMS sensors are characterized by high noise and large uncertainties in their outputs, including, but not limited to, bias, scale factor, non-orthogonalities, drifts, and noise characteristics, thereby limiting their stand-alone application.

Currently, one process of providing a continuous and reliable navigation solution includes studying characteristics of different sensor error sources and modeling the stochastic variation of these errors. Generally, random errors called “drifts” are modeled by sensor-error models. Examples of sensor-error models include the Gauss-Markov (GM) process and the Auto Regressive (AR) model. However, these traditional approaches employing GM or AR models and Allan variance methodology work unsatisfactorily for MEMS sensors and are time-consuming processes.

Another technique involves fusing sensor data with external aiding sources such as Global Positioning System (GPS) magnetometers to correct for these inherent MEMS errors by incorporating integration filters, which include, but are not limited to extended Kalman filters and particle filters. Although GPS is capable of providing accurate long term position and velocity information, the signals become interrupted or blocked when there is no direct line of sight to the satellites—for example, in urban environments or dense foliage. On the other hand, magnetometers are easily influenced by metallic objects in the environment, making the orientation data unreliable. Accordingly, a need exists for alternative and enhanced MEMS sensors.

### SUMMARY

In one embodiment, a Microelectromechanical (MEMS) based inertial measurement unit (IMU) system may include a MEMS sensor, a deep belief network, a processor, a memory communicatively coupled to the processor, the deep belief network, and the MEMS sensor, and machine readable instructions stored in the memory. The machine readable instructions may cause the MEMS based IMU system to perform at least the following when executed by the processor: use the MEMS sensor to generate a set of MEMS sensor data comprising random MEMS sensor errors; generate an error model based on the random MEMS sensor errors through the deep belief network; apply the error model to the set of MEMS sensor data to determine a calibrated orientation output of the MEMS sensor; and navigate based on the calibrated orientation output.

In another embodiment, a method for using a MEMS based IMU system including a MEMS sensor may include generating a set of MEMS sensor data from the MEMS sensor, the MEMS sensor data comprising random MEMS sensor errors, generating an error model based on the random MEMS sensor errors through using a deep belief network communicatively coupled to the MEMS sensor, applying the error model to the set of MEMS sensor data to determine a calibrated orientation output of the MEMS sensor, and navigating based on the calibrated orientation output.

In yet another embodiment, a method for training a deep belief network of a MEMS based IMU system including a MEMS sensor and for use with the MEMS sensor may include building the deep belief network through a stack of Restricted Boltzmann Machines (RBMs), associating a set of input-output sample pairs of data including a first data and a second data, and hierarchically training the stack of RBMs through a training algorithm based on the set of input-output sample pairs of data. Each RBM may include an input visible layer, a hidden layer, and a linking weight vector therebetween. The first data may be representative of data from the MEMS sensor and second data may be representative of data from a different sensor. The different sensor may include a GPS, an IMU unit, or combinations thereof. The training algorithm may be applied to the deep belief network prior to using the deep belief network as a trained deep belief network to generate an error model of the MEMS sensor. The method may further include generating the trained deep belief network based on the training algorithm, the trained deep belief network configured to independently mitigate sensor error of the MEMS sensor based on the error model.

### BRIEF DESCRIPTION OF THE DRAWINGS

FIG. 1 schematically illustrates MEMS sensor errors, according to one or more embodiments as shown and described herein;

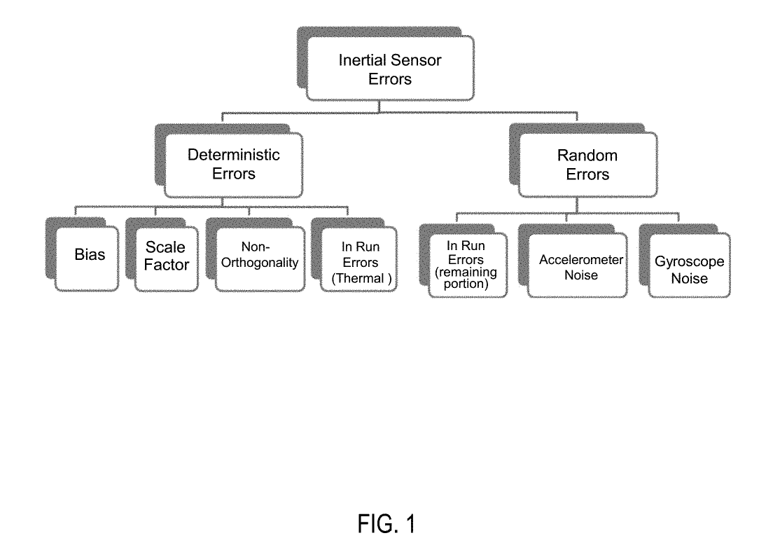

FIG. 2 schematically illustrates position errors due to uncompensated gyro bias, according to one or more embodiments as shown and described herein;

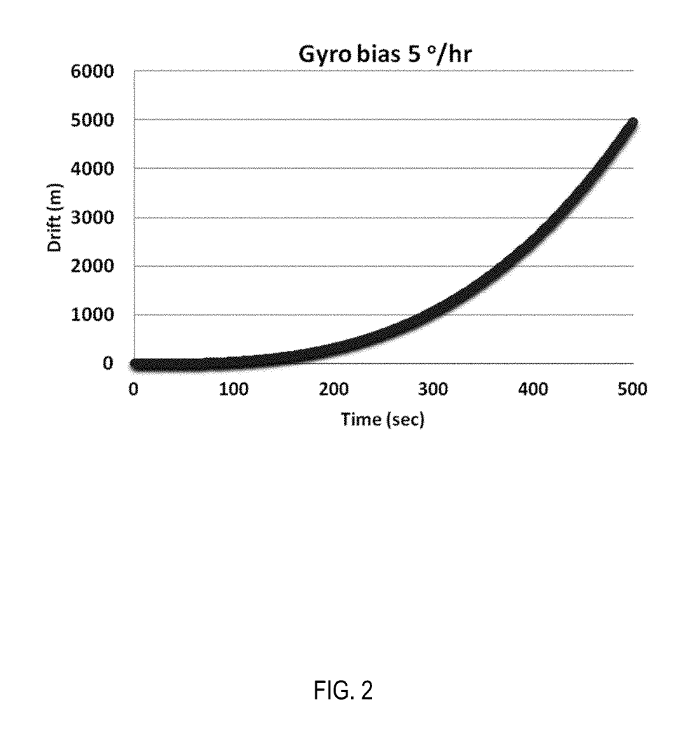

FIG. 3 schematically illustrates a Deep Belief Network (DBN) structure, according to one or more embodiments as shown and described herein;

FIG. 4 schematically illustrates a MEMS sensor and a system for implementing computer and software based methods to utilize the MEMS sensor including the DBN structure of FIG. 3, according to one or more embodiments as shown and described herein;

FIG. 5 schematically illustrates a process to determine a calibrated orientation output of the MEMS sensor utilizing the system of FIG. 4, according to one or more embodiments as shown and described herein; and

FIG. 6 schematically illustrates a process to train a deep belief network of the system of FIG. 4 for use with a MEMS sensor, according to one or more embodiments as shown and described herein.

### DETAILED DESCRIPTION

Embodiments of the present disclosure include methods for improving the performance of low-cost tactical grade MEMS IMUs to reach high-end tactical grade or inertial navigation grade performance levels comprising exploiting advanced Deep Learning and employing effective stochastic models for sensor errors that are difficult to obtain due to complex characteristics of these low-cost sensors. Embodiments of the present disclosure offer a SWaP-C alternative in a lower-cost, more compact weight platform than can be achieved with expensive and bulky higher grade Fiber Optic Gyroscopes and Ring Laser Gyroscopes.

Embodiments of the present disclosure present a self-contained, low-cost and self-correcting MEMS based inertial measurement system (IMU) that reaches the performance level of a high-end tactical grade IMU while maintaining the advantages of being small in size with low weight and power consumption. The accuracy is achieved by integration of MEMS IMU into a single Field Programmable Gate Array (FPGA) chip, together with advanced machine learning techniques (deep learning methodology).

Advances in MEMS technology in the past few years has enabled development of small size, weight, power and cost (SWaP-C) navigation and guidance systems to meet the fast growing market demand in areas of situational awareness, continuous area surveillance of border areas, protection of critical infrastructure or key assets and even in chemical and biological threat identification.

An Inertial Navigation System (INS) based on MEMS technology is a self-contained, three-dimensional, dead-reckoning navigation system that attains essential parameters through the use of a ten Degrees-Of-Freedom (10-DOF) inertial microsystem comprising a three-axis accelerometer, a three-axis gyroscope, a three-axis magnetometer and a barometer. Here, accelerometers measure linear motion along the x, y, and z axes (axial acceleration), while gyroscopes measure rotation (angular velocity) around these axes. However, these MEMS sensors are characterized by high errors, which may include bias instabilities, non-orthogonalities, drifts, and noise. For this reason, navigation grade Inertial Measurement Units (IMUs) are frequently employed instead of MEMS IMUs for critical applications where long term stability and a fully autonomous unit are mandatory. Currently, 10-DOF MEMS IMUs have yet to break into these high-precision dead-reckoning and guidance applications as errors due to MEMS gyroscopes limit their performance level. MEMS gyroscopes are prone to noise and bias drift that result in quadratic errors in velocity and cubic error in the position computations and thus, do not allow for extended periods of navigation. These errors build up over time, thereby corrupting the precision of the measurements.

Hence, the critical component in the development of a high performance MEMS based IMU is the development of gyroscopes with enhanced performance in terms of low Angle Random Walk (ARW), low bias drift, high scale-factor, and scale-factor stability. To provide a continuous and reliable long duration navigation solution; the characteristics of different error sources and the understanding of the stochastic variation of these errors are of significant importance.

### Random or Stochastic Errors

Stochastic errors occur due to random variations of bias or scale factor errors over time and are known as bias or scale factor drifts. The drift may also occur because of inherent sensor noise that interferes with the output signals, residual systematic errors, and residual run-to-run or in-run variation errors. Random errors are non-symmetric, cannot be separated from the actual data signal, and cannot be compensated by deterministic models. These random noises consist of a low frequency (long-term) component and a high frequency (short-term) component. The high frequency component exhibits white noise characteristics while the low frequency component is characterized by correlated noise and causes gradual change in errors during a run. There are number of stochastic or random processes available for modeling the random errors such as random constant, random walk, Gauss Markov (GM) process, and Auto Regressive (AR) models. Usually, these processes exploit the autocorrelation or Allan variance function of the noise to obtain first-order GM or other higher order auto-regressive model parameters. The value of the random walk parameters can be determined from the standard deviation of a sufficiently long static data, through correlation between values of the noise at different points in time (autocorrelation process) or by representing root-mean-square drift error as a function of averaged time (Allan variance technique). However, these traditional approaches work inadequately for MEMS sensors and are also time consuming.

Alternatively, artificial intelligence approaches utilizing Artificial Neural Network (ANN) have been utilized in modeling the MEMS errors and are reported to perform better than other conventional techniques. However, ANN suffers from poor generalization capability due to the presence of an elevated level of noises in the input-output data to be modeled. Hence, the ANN model prediction accuracy is poor and deteriorates after a short time. Also, the model development process requires longer time, which limits their use in real-time implementation. To alleviate this problem, use of Support Vector Machines (SVMs) based on the structural risk minimization principle has been suggested. As opposed to ANNs, SVMs require less training time and can avoid local minimization and over-fitting problems, thereby making them suitable for real-time implementation.

Embodiments of the present disclosure implement an enhanced Nu-Support Vector Regression (Nu-SVR) technique for modeling these random MEMS sensor errors under static conditions. In some embodiments, advanced machine learning techniques are exploited based on deep learning methodologies to improve the performance of low-cost tactical grade 10-DOF MEMS IMUs to reach performance levels of high-end tactical grade IMUs. This strategy would offer SWaP-C alternative in a low-cost, compact weight platform to expensive and bulky high cost and grade IMUs. Pattern learning capabilities of the deep learning technologies are employed, which can help to model noisy MEMS sensor data by recognizing large amount of salient features buried under noisy data measurements that are too complicated to be represented by a simple model.

### Deep Belief Network

The deep learning systems include multiple layers in which simple features are learned in lower-order layers and complex features are learned in higher-order layers. Feed-forward neural networks or Multi-Layered Perceptron (MLP) with several hidden layers are good examples of the deep model architecture. However, back-propagation, a popular learning algorithm for ANNs, does not work well for more numbers of hidden layers, as it requires labeled training data, gets stuck in local optima, and is slow under multiple hidden layer scenarios.

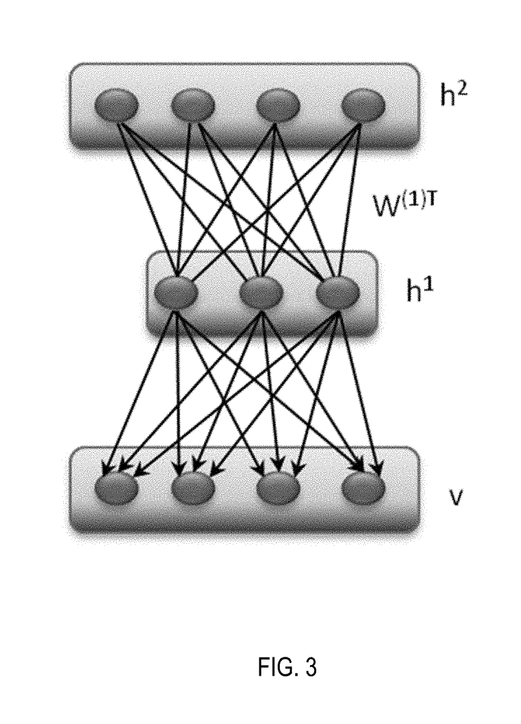

Deep Belief Network (DBN) is composed of a stack of Restricted Boltzmann Machines (RBMs), as illustrated in FIG. 3. DBN comes with a number of salient features. First, the learning algorithm makes effective use of unlabeled data. Second, it can be interpreted as a Bayesian probabilistic generative model composed of multiple layers of stochastic, hidden variables, which is immensely useful for stochastic error modeling. Third, the values of the hidden variables in the deepest layer are efficient to compute. And fourth, the over-fitting problem, which is often observed in the models with millions of parameters such as in DBNs, and the under-fitting problem, which occurs often in deep networks, can be effectively addressed by the generative pre-training step. In DBN model the joint distribution between the observed vector x and the l hidden layers is given by Equation 1.

P(x, h¹, . . . , h^{l})=Πₖ₌₀^{l-2}P(h^{k}|h^{k+1})P(h^{l-1},h^{l}) (Equation 1)

where x=h⁰, P(h^{k}|h^{k+1}) is a conditional distribution for the visible units conditioned on the hidden units of the RBM at a level k and P(h^{l-1}, h^{l}) is the visible hidden joint distributions in the top level RBM. Here, the hidden layers are organized as a binary random vector hⱼⁱ consisting of nⁱ elements, given by Equations 2 and 3.

$$\begin{matrix}P ( {h}^{k} \vert {h}^{k + 1} ) = {\prod }_{j = 0}^{{n}^{i}} P ( {h}_{j}^{i} \vert {h}^{i + 1} ) & ( Equation 2 ) \\ P ( {h}_{j}^{i} = 1 \vert {h}^{i + 1} ) = sigm ( {b}_{j}^{i} + {\sum }_{l = 1}^{{n}^{i + 1}} {w}_{lj}^{i} {h}_{l}^{i + 1} ) & ( Equation 3 )\end{matrix}$$

where sigm(t)=1/(1+e^{-t}), bⱼⁱ are biases for unit j of layer i and wⁱ is the weight matrix.

### Restricted Boltzmann Machines

The RBM, building blocks in DBN, includes a visible and a hidden layer of binary units connected by symmetrical weights but with no interconnections among units in the same layer. The network assigns a probability to each pair of visible v and hidden neuron-vectors h according to Equation 4.

$$P ( v , h ; θ ) = \frac{1}{Z ( θ )} {e}^{- E ( v , h ; θ )} \qquad ( Equation 4 )$$

where the partition function is given by Z(θ)=ΣᵥΣₕ exp(−E(v, h; θ)). The energy of the system is given by Equation 5.

E(v,h)=−a^{T}h−b^{T}v−v^{T}wh (Equation 5)

where wᵢⱼ represents a symmetric interaction term between visible unit i and hidden unit j and bᵢ, aⱼ are their biases. Now the probability assigned to a visible vector is obtained by marginalizing out hidden vector to yield the simplified Equation 6.

P(v|h;θ)=ΠᵢP(vᵢ|h)⇔P(vᵢ=1|h)=φ(bⱼ+Σⱼwᵢⱼhⱼ) (Equation 6)

Similarly, hidden vector is obtained by Equation 7.

P(h|v;θ)=ΠⱼP(jⱼ|v)⇔P(hⱼ=1|v)=φ(aⱼ+Σᵢwᵢⱼvᵢ) (Equation 7)

### DBN Training Algorithm

The learning procedure of DBNs consists of hierarchically training the stack of restricted Boltzmann machines. As shown above, RBM has an input visible layer, a hidden layer and a weight vector that links them. A goal of learning is to maximize w thereby maximizing the log likelihood log P(v; θ) function. Equation 8 was obtained by differentiating the above energy model.

−∂log P(v)/∂wᵢⱼ=<vᵢhⱼ>⁰−<vᵢhⱼ>^{∞} (Equation 8)

where <. . . > denotes the expectation of random variable, <vᵢhⱼ>⁰ is positive gradient and <vᵢhⱼ>^{∞} is negative gradient.

To obtain these gradients, Gibbs sampling can be used but it time consuming and requires many iterations. Instead, Contrastive Divergence (CD) approximation to the gradients will be exploited here while Gibbs sampling will be used in the initial step. With contrastive divergence method and Gibbs-sampling, the weight vectors in one layer of RBM can be learned.

For multilayer RBM, a greedy layer-by-layer training algorithm will be employed. This learning algorithm can find a good set of model parameters fairly quickly, even for models that contain many layers of nonlinearities and millions of parameters. Accordingly, one RBM (v,h₁) is learned and then stacked with another RBM (₁,h₂) where the sampled h₁ via the learned weight w₁ becomes the visible input data in the second RBM and use the same approach to learn the second RBM. This procedure goes on until all the layers are learned.

In some embodiments, DBN is trained in a supervised manner by providing set of input-output sample pairs [(x_{1,1}), . . . , (xₗ,y_{y})], where x represents data coming from MEMS sensors and y is the data from GPS or high cost IMU unit. Once sufficient training of the DBN based model occurs, the same model may be applied to compensate and mitigate sensor errors for different yet same grade sensors. Also, this training occurs only once, under all environmental conditions with external source to establish the true readings (GPS or high grade IMU).

After training, the formulated model will keep the MEMS sensor errors in check irrespective of the presence or absence of other aiding sources. Here, DBN is trained in a supervised manner, but it can also be effectively trained under unsupervised conditions. This avenue is explored in the event that aiding source is not available. Once sufficient training of the deep learning based model occurs, the same model may be applied to compensate and mitigate sensor errors for different yet same grade MEMS sensors. This will substantially reduce the overall system cost while making MEMS sensors viable for more critical applications. In summary, embodiments of the present disclosure would offer more than 10 times better size, weight, power, and cost performance than most MEMS based IMUs and matching or exceeding most FOG and RLG based IMU systems in the market today.

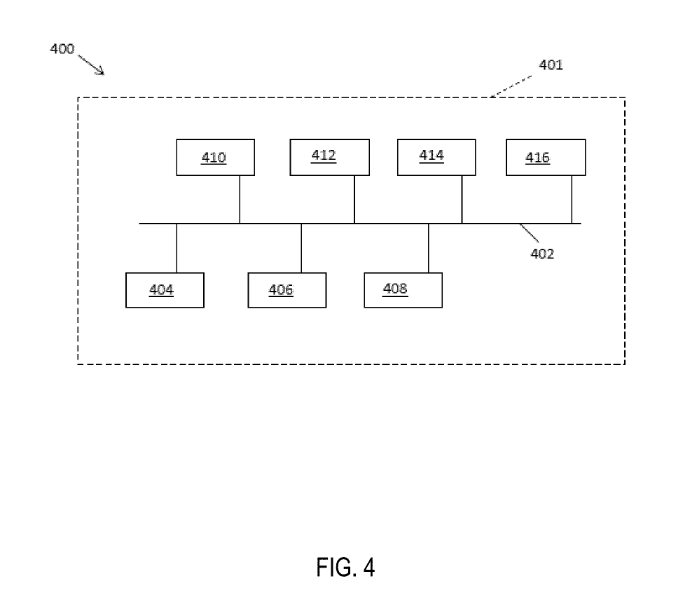

Referring to FIG. 4, a system 400 for implementing computer and software based methods to utilize a MEMS sensor 401 including the DBN structure of FIG. 3 is illustrated. The system 400 includes a communication path 402, one or more processors 404, a memory component 406, a deep learning system module 408, and MEMS sensor components including at least one of an accelerometer 410, a gyroscope 412, a barometer 414, and a magnetometer 416, or combinations thereof. The deep learning system module 408 is configured to incorporate the DBN structure of FIG. 3 and implement the DBN training algorithm as described herein. The MEMS sensor 401 is a MEMS based sensor as described herein and may be configured for self-driving, mobile, and wearable applications, or combinations thereof.

Internal components of the MEMS sensor 401 as a sensor device is schematically illustrated. FIG. 4 depicts the MEMS sensor 401 for estimating an orientation and/or position of the MEMS sensor 401 (and/or the orientation of an object or device incorporating the MEMS sensor 401) embodied as hardware, software, and/or firmware, according to embodiments shown and described herein. It is noted that computer-program products and methods for correcting the output of the MEMS sensor 401 may be executed by any combination of hardware, software, and/or firmware.

The MEMS sensor 401 illustrated in FIG. 4 comprises and/or is communicatively coupled to the one or more processors 404, the memory component 406 such as a non-transitory computer-readable memory (which may store computer readable instructions (i.e., software code) for performing the various functionality described herein, such as computing orientation of the sensor device, for example), the deep learning system module 408, the at least one accelerometer 410 (e.g. a multi-axis accelerometer sensor), the at least one gyroscope 412 (e.g., a multi-axis gyroscope sensor), the at least one barometer 414 (e.g., a MEMS barometer), the at least one magnetometer 416 (e.g., a multi-axis magnetometer), or combinations thereof. Each of the illustrated components may be communicatively coupled to the one or more processors 404 through the communication path 402 (e.g., by a communication bus) which one or more processors 404 may be configured as any processor, micro-controller, or the like, capable of executing computer readable instructions stored in the memory component 406 or otherwise provided as software and/or firmware. It should be understood that the components illustrated in FIG. 4 are merely exemplary and are not intended to limit the scope of this disclosure.

The memory component 406 may include a non-transitory computer-readable memory that may be configured as nonvolatile computer readable medium and, as such, may include random access memory (including SRAM, DRAM, and/or other types of random access memory), flash memory, registers, compact discs (CD), digital versatile discs (DVD), magnetic disks, and/or other types of storage components. Additionally, the non-transitory computer-readable memory may be configured to store, among other things, computer readable instructions, one or more look-up tables, and any data necessary to compute the position and/or orientation outputs of MEMS sensor 401 described below.

As stated above, the one or more processors 404 may include any processing component configured to receive and execute instructions (such as from the memory component 406). It is noted that the calculations described herein may be effectuated by the one or more processors 404 as software instructions stored on the memory component 406, as well as by any additional controller hardware, if present (not shown). In some embodiments, the additional controller hardware may comprise logic gates to perform the software instructions as a hardware implementation. The one or more processors 404 may be configured as, but not limited to, a general-purpose microcontroller, an application-specific integrated circuit, or a programmable logic controller.

The MEMS sensor 401 may include one or more sensor devices that may be incorporated into larger systems, and may be able to communicate with external devices and components of such systems via input/output hardware (not shown). The input/output hardware may include any hardware and/or software for sending and receiving data to an external device, such as an output signal corresponding to a position and/or an orientation estimation of the MEMS sensor 401. Exemplary input/output hardware includes, but is not limited to, universal serial bus (USB), FireWire, Thunderbolt, local area network (LAN) port, wireless fidelity (Wi-Fi) card, WiMax card, and/or other hardware for communicating with other networks and/or external devices.

As described in more detail below, each of the sensor components including the one or more accelerometers 410, gyroscopes 412, barometers 414, and/or magnetometers 416 may be configured to provide a signal to the processor 102 (or other components of the sensor device 100) that corresponds with a physical quantity that represents a physical position and/or orientation of the MEMS sensor 401. The signal or data from the various sensor components may be provided to the one or more processors 404 and/or additional controller hardware. For example, the accelerometer 410 may be configured to provide a signal/data that corresponds to its orientation relative to gravity, while the magnetometer 416 may be configured to provide a signal/data that corresponds to its orientation relative to magnetic North, and the gyroscope 412 may be configured to provide a signal/data that corresponds to its position with respect to x-, y- and z-axes. The accelerometer 410, the gyroscope 412, the barometer 414, and the magnetometer 416 may be configured as any proprietary, currently available, or yet-to-be-developed sensor device. It should be understood that the MEMS sensor 401 may include any combination of accelerometers 410, gyroscopes 412, barometers 414, and/or magnetometers 416 (or other sensors that output a sensor vector corresponding to position and/or orientation).

In embodiments, the deep learning system module 408 may implement a deep learning algorithm that is configured to utilize a neural network, and the neural network may be customizable. The deep learning algorithm may be implemented by a deep model architecture configured to utilize a convolutional neural network that, in a field of machine learning, for example, is a class of deep, feed-forward neural networks or MLP with several hidden layers.

The system 400 including the deep learning system module 408 is configured to apply the deep learning algorithm as described herein to train and provide machine learning capabilities to a neural network associated with the deep learning algorithm as described herein. The deep learning system module 408 is coupled to the communication path 402 and communicatively coupled to the one or more processors 404, which may process the input signals received from the system modules and/or extract information from such signals.

Data stored and manipulated in the system 400 as described herein is utilized by the deep learning system module 408 to apply Machine Learning and Artificial Intelligence. This machine learning application may create models that can be applied by the system 400, to make it more efficient and intelligent in execution. As an example and not a limitation, the deep learning system module 408 may include components selected from the group consisting of an artificial intelligence engine, Bayesian inference engine, and a decision-making engine, and may have an adaptive learning engine further comprising a deep neural network learning engine.

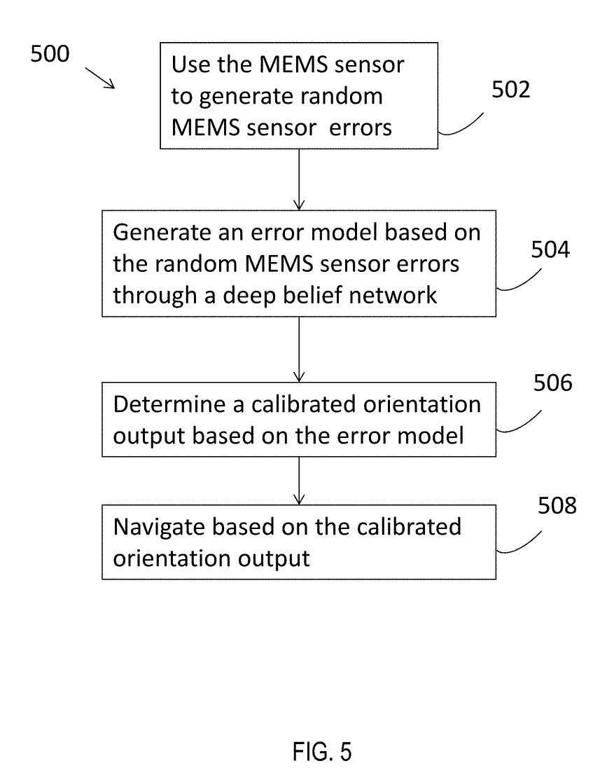

Referring to FIG. 5, a process 500 to determine a calibrated orientation output of the MEMS sensor 401 utilizing the system 400 of FIG. 4 is illustrated. The system 400 may be a MEMS based IMU system including the MEMS sensor, a deep belief network of the deep learning system module 408, a processor 404, a memory such as the memory component 406 communicatively coupled to the processor 404, the deep belief network of the deep learning system module 408, and the MEMS sensor 401, and machine readable instructions stored in the memory. The machine readable instructions may cause the system 400 based on the MEMS based IMU to perform at least the process 500 when executed by the processor. The process 500 includes block 502 for use of the MEMS sensor 401 to generate a set of MEMS sensor data comprising random MEMS sensor errors. In block 504, an error model is generated based on the random MEMS sensor errors through the deep belief network. In block 506, the error model is applied to the set of MEMS sensor data to determine a calibrated orientation output of the MEMS sensor 401. In block 508, navigation occurs based on the calibrated orientation output. The MEMS sensor 401 may be configured for self-driving, mobile, and wearable applications, or combinations thereof.

In embodiments, the deep belief network of the deep learning system module 408 may include a stack of Restricted Boltzmann Machines (RBMs), and the deep belief network is configured to apply a learning algorithm using unlabeled data, generate a Bayesian probabilistic generative model comprising multiple layers of stochastic, hidden variables for stochastic error modeling to generate the error model, compute values of the hidden variables in a deepest layer, and/or address an over-fitting problem and an under-fitting problem through application of a generative pre-training algorithm to learn the stack of RBMs. The generative pre-training algorithm may be applied to the deep belief network prior to using the deep belief network to generate the error model. The generative pre-training algorithm may utilize a set of input-output sample pairs of data including a first data and a second data, the first data representative of data from the MEMS sensor 401 and second data representative of data from a different sensor, wherein the different sensor comprises a GPS, an IMU unit, or combinations thereof.

Referring to FIGS. 3-4, the deep belief network of the deep learning system module 408 may include a plurality of layers comprising lower-order layers and higher-order layers, a plurality of simple features configured to be learned in the lower-order layers, and a plurality of complex features configured to be learned in the higher-order layers. By way of example, and not as a limitation, when the deep belief network include a stack of RBMs, each RBM may include a visible layer of binary units and a hidden layer of binary units. The visible layer and the hidden layer are connected by symmetrical weights, and units in each of the visible layer and the hidden layer are not interconnected within a respective same layer.

Referring to the process 500 of FIG. 5, and according to Equation 4 above, the process 500 may further include assigning a probability to each pair of visible vectors and hidden-neuron vectors disposed between the visible layer of binary units and the hidden layer of binary units. Each of a partition function, as described herein, and an energy function as described herein as Equation 5 is based on the pairs of visible vectors and hidden-neuron vectors. As describe above, a probability assigned to a visible vector by marginalizing out an associated hidden vector as shown in Equation 6, and a probability assigned to a hidden vector may be generated by marginalizing out an associated visible vector as shown in Equation 7.

In embodiments when the deep belief network includes a stack of RBMs, the training algorithm is applied to the deep belief network prior to using the deep belief network to generate the error model, each RBM includes an input visible layer, a hidden layer, and a linking weight vector therebetween, and the training algorithm is configured to hierarchically train the stack of RBMs. As described above with respect to Equation 8, a set of associated gradients may be obtained through the training algorithm to maximize each weight vector to maximize a log likelihood function. The set of associated gradients may be obtained through using Gibbs sampling in an initial step, and subsequently using a Contrastive Divergence method to learn the weight vectors in one layer of RBM. Further, a greedy layer-by-layer training algorithm may be employed for a multi-layer RBM to learn one RBM stack at a time through a learning process. The learning process may include learning a first RBM stack, learning a subsequent second RBM stack, and repeating the learning process until all the layers of the stack of RBMS are learned. As a non-limiting example, the first RBM stack may be learned through learning a weight vector and a sampled hidden vector via the weight vector in the first RBM stack, and a subsequent second RBM may be learned through using the sampled hidden vector of the first RBM stack as visible input data in the subsequent second RBM to learn the second subsequent second RBM

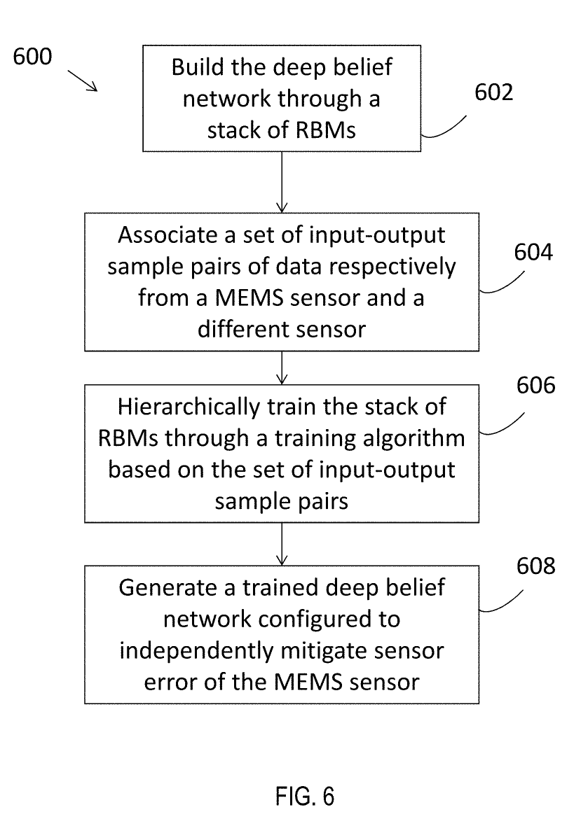

Referring to FIG. 6, a process 600 to train a deep belief network of the deep learning system module 408 of the system 400 of FIG. 4 for use with a MEMS sensor 401 is illustrated. In block 602 of the process 600, the deep belief network is built through a stack of Restricted Boltzmann Machines (RBMs). Each RBM may include an input visible layer, a hidden layer, and a linking weight vector therebetween. The process 600 associates and/or utilizes a set of input-output sample pairs of data including a first data and a second data in block 604. The first data may be representative of data from the MEMS sensor 401 and second data may be representative of data from a different sensor. The different sensor may include a GPS, an IMU unit, or combinations thereof. In block 606, the stack of RBMs is hierarchically trained through a training algorithm based on the set of input-output sample pairs of data. The training algorithm may be applied to the deep belief network prior to using the deep belief network as a trained deep belief network to generate an error model of the MEMS sensor 401. In block 608, the trained deep belief network is generated based on the training algorithm. The trained deep belief network may be configured to independently mitigate sensor error of the MEMS sensor based on the error model. The trained deep belief network may additionally be configured to independently mitigate sensor error of one or more alternative MEMS sensors comprising a same grade as the MEMS sensor 401.

Unless otherwise defined, all technical and scientific terms used herein have the same meaning as commonly understood by one of ordinary skill in the art to which the claimed subject matter belongs. The terminology used in the description herein is for describing particular embodiments only and is not intended to be limiting. As used in the specification and appended claims, the singular forms “a,” “an,” and “the” are intended to include the plural forms as well, unless the context clearly indicates otherwise.

It is noted that terms like “preferably,” “commonly,” and “typically” are not utilized herein to limit the scope of the appended claims or to imply that certain features are critical, essential, or even important to the structure or function of the claimed subject matter. Rather, these terms are merely intended to highlight alternative or additional features that may or may not be utilized in a particular embodiment.

What is claimed is:

1. A Microelectromechanical (MEMS) based inertial measurement unit (IMU) system comprising:
a MEMS sensor;
a deep belief network;
a processor;
a memory communicatively coupled to the processor, the deep belief network, and the MEMS sensor; and
machine readable instructions stored in the memory that cause the MEMS based IMU system to perform at least the following when executed by the processor:
use the MEMS sensor to generate a set of MEMS sensor data comprising random MEMS sensor errors;
generate an error model based on the random MEMS sensor errors through the deep belief network;
apply the error model to the set of MEMS sensor data to determine a calibrated orientation output of the MEMS sensor; and
navigate based on the calibrated orientation output.

2. The MEMS based IMU system of claim 1, wherein the MEMS sensor is configured for self-driving, mobile, and wearable applications, or combinations thereof.

3. The MEMS based IMU system of claim 1, wherein the deep belief network comprises a stack of Restricted Boltzmann Machines (RBMs), and the deep belief network is configured to:
apply a learning algorithm using unlabeled data;
generate a Bayesian probabilistic generative model comprising multiple layers of stochastic, hidden variables for stochastic error modeling to generate the error model;
compute values of the hidden variables in a deepest layer; and
address an over-fitting problem and an under-fitting problem through application of a generative pre-training algorithm to learn the stack of RBMs.

4. The MEMS based IMU system of claim 3, wherein the generative pre-training algorithm is applied to the deep belief network prior to using the deep belief network to generate the error model, and the generative pre-training algorithm utilizes a set of input-output sample pairs of data including a first data and a second data, the first data representative of data from the MEMS sensor and second data representative of data from a different sensor, wherein the different sensor comprises a GPS, an IMU unit, or combinations thereof.

5. A method for using a Microelectromechanical (MEMS) based inertial measurement unit (IMU) system including a MEMS sensor, the method comprising:
generating a set of MEMS sensor data from the MEMS sensor, the MEMS sensor data comprising random MEMS sensor errors;
generating an error model based on the random MEMS sensor errors through using a deep belief network communicatively coupled to the MEMS sensor;
applying the error model to the set of MEMS sensor data to determine a calibrated orientation output of the MEMS sensor; and
navigating based on the calibrated orientation output.

6. The method of claim 5, wherein the deep belief network comprises a plurality of layers comprising lower-order layers and higher-order layers, a plurality of simple features configured to be learned in the lower-order layers, and a plurality of complex features configured to be learned in the higher-order layers.

7. The method of claim 5, wherein the deep belief network comprises a stack of Restricted Boltzmann Machines (RBMs).

8. The method of claim 7, wherein each RBM comprises a visible layer of binary units and a hidden layer of binary units, the visible layer and the hidden layer are connected by symmetrical weights, and units in each of the visible layer and the hidden layer are not interconnected within a respective same layer.

9. The method of claim 8, further comprising assigning a probability to each pair of visible vectors and hidden-neuron vectors disposed between the visible layer of binary units and the hidden layer of binary units, wherein each of a partition function and an energy function is based on the pairs of visible vectors and hidden-neuron vectors.

10. The method of claim 9, further comprising generating a probability assigned to a visible vector by marginalizing out an associated hidden vector, and generating a probability assigned to a hidden vector by marginalizing out an associated visible vector.

11. The method of claim 5, further comprising applying a training algorithm to the deep belief network prior to using the deep belief network to generate the error model.

12. The method of claim 11, wherein the deep belief network comprises a stack of Restricted Boltzmann Machines (RBMs), each RBM comprises an input visible layer, a hidden layer, and a linking weight vector therebetween, and the training algorithm is configured to hierarchically train the stack of RBMs.

13. The method of claim 12, further comprising obtaining a set of associated gradients through the training algorithm to maximize each weight vector to maximize a log likelihood function.

14. The method of claim 13, wherein obtaining the set of associated gradients comprises:
using Gibbs sampling in an initial step; and
subsequently using a Contrastive Divergence method to learn the weight vectors in one layer of RBM.

15. The method of claim 13, further comprising employing a greedy layer-by-layer training algorithm for a multi-layer RBM to learn one RBM stack at a time through a learning process.

16. The method of claim 15, the learning process comprising learning a first RBM stack, learning a subsequent second RBM stack, and repeating the learning process until all the layers of the stack of RBMS are learned.

17. The method of claim 16, wherein:
learning the first RBM stack comprises learning a weight vector and a sampled hidden vector via the weight vector in the first RBM stack; and
learning a subsequent second RBM comprises using the sampled hidden vector of the first RBM stack as visible input data in the subsequent second RBM to learn the second subsequent second RBM.

18. The method of claim 11, wherein applying the training algorithm comprises:
utilizing a set of input-output sample pairs of data including a first data and a second data, the first data representative of data from the MEMS sensor and second data representative of data from a different sensor, wherein the different sensor comprises a GPS, an IMU unit, or combinations thereof.

19. A method for training a deep belief network of a Microelectromechanical (MEMS) based inertial measurement unit (IMU) system including a MEMS sensor and for use with the MEMS sensor, the method comprising:
building the deep belief network through a stack of Restricted Boltzmann Machines (RBMs), wherein each RBM comprises an input visible layer, a hidden layer, and a linking weight vector between the input visible layer and the hidden layer;
associating a set of input-output sample pairs of data including a first data and a second data, the first data representative of data from the MEMS sensor and second data representative of data from a different sensor, wherein the different sensor comprises a GPS, an IMU unit, or combinations thereof;
hierarchically training the stack of RBMs through a training algorithm based on the set of input-output sample pairs of data, wherein the training algorithm is applied to the deep belief network prior to using the deep belief network as a trained deep belief network to generate an error model of the MEMS sensor; and
generating the trained deep belief network based on the training algorithm, the trained deep belief network configured to independently mitigate sensor error of the MEMS sensor based on the error model.

20. The method of claim 19, wherein the trained deep belief network is configured to independently mitigate sensor error of one or more alternative MEMS sensors comprising a same grade as the MEMS sensor.
